(19) United States
(12) Patent Application Publication
(10) Pub. No.: US 2021/0391146 A1
(43) Pub. Date: Dec. 16, 2021

(54) RF FREQUENCY CONTROL AND GROUND PATH RETURN IN SEMICONDUCTOR PROCESS CHAMBERS

(71) Applicant: APPLIED MATERIALS, INC., Santa Clara, CA (US)

(72) Inventors: Timothy Joseph FRANKLIN, Campbell, CA (US); Rajinder DHINDSA, Pleasanton, CA (US); Daniel Sang BYUN, Campbell, CA (US); Carlaton WONG, Sunnyvale, CA (US); Joseph PERRY, San Jose, CA (US); James Hugh ROGERS, Los Gatos, CA (US)

(21) Appl. No.: 16/899,326

(22) Filed: Jun. 11, 2020

(51) Int. Cl. H01J 37/32; H01L 21/67

(52) U.S. Cl. CPC H01J 37/32165; H01J 37/32091; H01J 37/32623; H01L 21/67069; H01J 37/32568

(57) ABSTRACT

Methods and apparatus for processing a substrate are provided herein. In some embodiments, a method of processing a substrate in an etch process chamber includes: pulsing RF power from an RF bias power supply to a lower electrode disposed in a substrate support of the etch process chamber at a first frequency of about 200 kHz to about 700 kHz over a first period to create a plasma in a process volume of the etch process chamber, wherein a conductance liner surrounds the process volume to provide a ground path for an upper electrode of the etch process chamber; and pulsing RF power from the RF bias power supply to the lower electrode at a second frequency of about 2 MHz to about 13.56 MHz over the first period.

### FIELD

Embodiments of the present principles generally relate to semiconductor processing equipment.

### BACKGROUND

Deposition and etch chambers used in the manufacturing of semiconductor devices need to produce consistent and uniform results for every substrate that is processed. To further enhance processing, plasma can be used in both deposition and etching of materials. The plasma can be generated through inductive coupling or capacitive coupling. In capacitively coupled plasma chambers, conductance liners are used to contain the plasma generated in a process volume of the chamber and to provide an RF ground return path. Unconfined plasmas cause etch-byproduct deposition on the chamber walls and could also etch the chamber walls. Etch-byproduct deposition on the chamber walls could cause the process to drift. The conductance liners generally surround the process volume except where interrupted by substrate transfer slots. The substrate transfer slots allow robotic arms to place substrates into and out of the process volume of the plasma chamber. The inventors have also observed that the presence of the substrate transfer slot interferes with the uniformity of the deposition on the substrate during processing.

Thus, the inventors have provided improved methods and apparatus that increase deposition uniformity on substrates.

### SUMMARY

Methods and apparatus for processing a substrate are provided herein. In some embodiments, a method of processing a substrate in an etch process chamber includes: pulsing RF power from an RF bias power supply to a lower electrode disposed in a substrate support of the etch process chamber at a first frequency of about 200 kHz to about 700 kHz over a first period to create a plasma in a process volume of the etch process chamber, wherein a conductance liner surrounds the process volume to provide a ground path for an upper electrode of the etch process chamber; and

pulsing RF power from the RF bias power supply to the lower electrode at a second frequency of about 2 MHz to about 13.56 MHz over the first period.

In some embodiments, an etch process chamber, includes: a process chamber having a process volume therein; a conductance liner surrounding the process volume, the conductance liner having a C-shaped profile; and a substrate support assembly disposed in the processing volume, wherein the substrate support assembly includes an electrostatic chuck assembly coupled to a power supply and a lower electrode coupled to an RF bias power supply to provide RF power at two or more frequencies simultaneously to the substrate support assembly.

In some embodiments, a process chamber defining a process volume therein; a conductance liner surrounding the process volume; a substrate support disposed in the processing volume, wherein the substrate support includes a puck having a first electrode embedded therein and coupled to a chucking power supply and a second electrode embedded therein and coupled to a second RF power supply, wherein the second RF power supply provides a first frequency of about 200 kHz to about 700 kHz, and provides a second frequency of about 2 MHz to about 13.56 MHz, wherein the first frequency and the second frequency configured to be provided simultaneously; and an upper electrode having gas passages coupled to the process volume, wherein the conductance liner is disposed about the upper electrode.

Other and further embodiments are disclosed below.

### BRIEF DESCRIPTION OF THE DRAWINGS

Embodiments of the present principles, briefly summarized above and discussed in greater detail below, can be understood by reference to the illustrative embodiments of the principles depicted in the appended drawings. However, the appended drawings illustrate only typical embodiments of the principles and are thus not to be considered limiting of scope, for the principles may admit to other equally effective embodiments.

FIG. 1 depicts a cross-sectional view of a process chamber for semiconductor processing in accordance with some embodiments of the present principles.

FIG. 2 depicts a cross-sectional view of a process chamber with a movable conductance liner in accordance with some embodiments of the present principles.

FIG. 3 depicts a cross-sectional view of a process chamber with a movable conductance liner in a lowered position in accordance with some embodiments of the present principles.

FIG. 4 depicts a cross-sectional view of a movable portion in accordance with some embodiments of the present principles.

FIG. 5 depicts a cross-sectional view of a process chamber with a movable conductance liner with a split vertical sidewall in accordance with some embodiments of the present principles.

FIG. 6 depicts a cross-sectional view of a movable portion with a split vertical sidewall in accordance with some embodiments of the present principles.

FIG. 7 depicts a cross-sectional view of a process chamber with a movable conductance liner with a movable vertical sidewall in accordance with some embodiments of the present principles.

FIG. 8 depicts a cross-sectional view of a movable portion in accordance with some embodiments of the present principles.

FIG. 9 depicts an isometric view of a two-piece movable conductance liner in accordance with some embodiments of the present principles.

FIG. 10 depicts an isometric view of a split vertical sidewall movable conductance liner in accordance with some embodiments of the present principles.

FIG. 11 depicts an isometric view of a three-piece movable conductance liner in accordance with some embodiments of the present principles.

FIG. 12 is a method of cleaning a process chamber with a movable conductance liner in accordance with some embodiments of the present principles.

FIG. 13 is a method of processing a substrate in an etch process chamber in accordance with some embodiments of the present principles.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

The methods and apparatus described herein provide improved deposition uniformity in plasma process chambers. An RF bias power supply provides RF power to a lower electrode of the plasma process chamber. The RF bias power supply is a mixed frequency RF power supply configured to provide RF power at different frequencies over a first period to the lower electrode to advantageously improve deposition or etching. In some embodiments, the RF bias power supply is configured to process a substrate at two or more frequencies over the first period.

Plasma confinement liners or conductance liners facilitate in keeping a plasma within the plasma process chamber's process volume and provide an RF ground return path during processing. The embodiments of confinement liners provided herein also provide enhanced flow conductance therethrough. In some embodiments, the confinement liner may be made from a material that is electrically conductive to provide a ground path return for the RF power supply when the plasma is in contact with the confinement liner.

The inventor has found that any disruption with the RF ground return path in the conductance liner causes uniformity issues during deposition. The inventor discovered that substrate transfer slots used for placing substrates into and out of the process volume of the process chamber are a source of uniformity issues as the substrate transfer slot breaches the conductance liner. The substrate transfer slot disrupts the smoothness of the inner surface of the conductance liner and affects the current flow through the conductance liner. For plasma to be generated evenly and consistently, the process volume should provide a conductance liner with a smooth, even inner surface and with a uniform thickness to provide a uniform current path for the RF return. The methods and apparatus of the present principles provide a 360-degree conductance liner that provides both a smooth uninterrupted inner surface and an even thickness on all vertical walls to further enhance deposition uniformity.

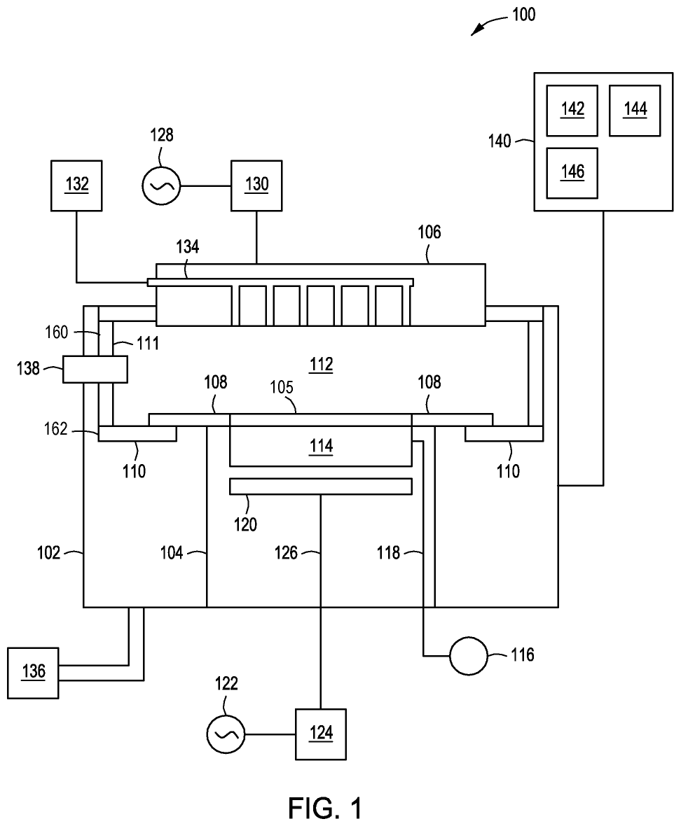

The methods and apparatus of the present principles can be applied to, for example, capacitively coupled plasma chambers such as that illustrated in FIG. 1. FIG. 1 shows a cross-sectional view 100 of a process chamber 102 that includes a substrate support assembly 104 and an upper electrode 106. A substrate 105 is disposed on the substrate support assembly 104. An edge ring 108 is disposed about the substrate 105 and interfaces with a conductance liner 110 and the substrate support assembly 104. The upper electrode 106, the conductance liner 110, and the edge ring 108 help to define a process volume 112. In some embodiments, the conductance liner 110 may be made from a material that is electrically conductive to provide a ground path for a RF power supply when the plasma is in contact with the conductance liner 110. For example, in some embodiments, the conductance liner 110 is made of a material having an electrical resistivity less than or equal to 0.01 ohms per cm. In some embodiments, the conductance liner 110 may be made of a material that reduces or prevents contamination of a substrate being processed.

The substrate support assembly 104 includes an electrostatic chuck (ESC) assembly 114 that is electrically connected via a first conductor 118 to a power supply 116. The power supply 116 provides, for example, DC voltage to the ESC assembly 114 to electrostatically clamp substrates to the substrate support assembly 104. The substrate support assembly 104 also includes a lower electrode 120 that is electrically connected via a second conductor 126 to an RF bias power supply 122 via an RF bias matching network 124. The upper electrode 106 is electrically connected to an RF power supply 128 via an RF matching network 130. In some embodiments, the RF power supply 128 is configured to provide RF power at a frequency of about 2 MHz to about 120 MHz. In some embodiments, the upper electrode 106 is grounded. The upper electrode 106 may also include gas passages 134 that are fluidly connected to a gas supply 132. In some embodiments, the upper electrode 106 is made of a same material as the conductance liner 110. A vacuum pump 136 assists in removing byproducts and/or gases from the process chamber 102.

In some embodiments, the RF bias power supply 122 is a mixed frequency RF power supply, providing multiple power levels at multiple frequencies, e.g., two frequencies, three frequencies, or the like, to improve deposition or etching. The multiple frequencies may be independently pulsed, phased, and/or duty cycle controlled over a first period via a controller 140 (discussed more in detail below). Further, the multiple frequencies may be pulsed synchronously or asynchronously over the first period. Each of the multiple frequencies may have a pulse envelope having a pulse duration, a pulse “on” time, a pulse “off” time, a pulse frequency, and a pulse duty cycle. The pulse duration is the sum of the pulse “on” and “off” times. A pulse duty cycle for each frequency is the pulse “on” time divided by the pulse duration. In some embodiments, the first period may coincide with a pulse duration of one of the multiple frequencies. In some embodiments, the first period may be greater than a pulse duration of any of the multiple frequencies.

In some embodiments, the multiple frequencies are synchronized together in such a manner that they have identical phase and duty cycle and therefore a phase difference of zero between them. In some embodiments, the multiple frequencies are varied in phase, for example having phase differences of 0°, 90°, 180° and 270°, respectively, where the phase difference is defined by how much the second pulse output lags the first pulse output. In some embodiments, etching rates may be enhanced while pulsing the plasma by controlling the phase lead or lag of the RF power envelopes. In some embodiments, when the RF power supply 128 and multiple frequencies provided by the RF bias power supply 122 are pulsed independently out-of-phase, or with varying duty cycle, the different plasma dynamics of the varying frequencies allow for better plasma fill over the entire pulse.

In some embodiments, the RF bias power supply 122 may provide dual frequency powers, both a high frequency and a low frequency power over the first period. Utilization of a dual frequency RF power supply, particularly for the RF bias power supply 122, improves film deposition. A first frequency of about 200 kHz to about 2.0 MHz (e.g., a low frequency) improves implantation of species into the deposited film, while a second frequency of about 2.0 MHz to about 120 MHz (e.g., a high frequency) increases ionization and deposition or etching rate of the film. In some embodiments, the first frequency is about 400 kHz. In some embodiments, the second frequency is about 2.0 MHz. The first frequency and the second frequency may be pulsed synchronously or pulsed asynchronously (e.g., out of phase).

In some implementations, the RF bias power supply 122 is a mixed frequency RF power supply configured to provide RF power at three different frequencies over the first period to the substrate support assembly 104 to advantageously improve deposition or etching. In one example, the RF bias power supply 122 provides a first frequency of about 200 kHz to about 700 kHz over the first period to improve ion energy distribution, while providing a second frequency of about 2 MHz to about 13.56 MHz over the first period to improve implantation of species into the deposited film, and providing a third frequency of about 13.56 MHz to about 120 MHz over the first period to increase ionization and deposition or etching rate of the film. In some embodiments, the first frequency is about 350 kHz to about 450 kHz. In some embodiments, the first frequency is about 400 kHz. In some embodiments, the first frequency is pulsed. In some embodiments, the second frequency is about 2 MHz to about 6 MHz. In some embodiments, the second frequency is pulsed. In some embodiments, the third frequency is about 35 MHz to about 45 MHz. In some embodiments, the third frequency is about 40 MHz. In some embodiments, the third frequency is pulsed.

In some embodiments, the first frequency, the second frequency, and the third frequency may be pulsed synchronously. In some embodiments, two of the first frequency, the second frequency, and the third frequency may be pulsed synchronously, while the remaining of the first frequency, the second frequency, and the third frequency is pulsed asynchronously (e.g., out of phase) with the other two. In some embodiments, the first frequency, the second frequency, and the third frequency are all pulsed asynchronously (e.g., out of phase) with respect to each other.

One or both of the RF power supply 128 and the RF bias power supply 122 are utilized in creating or maintaining a plasma in the process volume 112. For example, the RF bias power supply 122 may be utilized during a deposition process and the RF power supply 128 may be utilized during an etching process. In some deposition processes, the RF power supply 128 is used in conjunction with the RF bias power supply 122. During a deposition or etch process, one or both of the RF power supply 128 and the RF bias power supply 122 provide a power of about 100 watts (W) to about 20,000 W in the process volume 112 to facilitation ionization of a precursor gas. In one embodiment, which can be combined with other embodiments described herein, at least one of the RF power supply 128 and the RF bias power supply 122 are pulsed.

The controller 140 controls the operation of the process chamber 102 using a direct control or indirect control via other computers (or controllers) associated with the process chamber 102. In operation, the controller 140 enables data collection and feedback from the process chamber 102 and peripheral systems to optimize performance of the process chamber 102. For example, the controller 140 may be configured to receive a process recipe for processing the substrate 105 in the process chamber 102 and configured to independently control a pulse duration, phase, and duty cycle of each of the multiple frequencies provided to the lower electrode 120 over the first period. The controller 140 is programmable to apply pulse control signals for each of the multiple frequencies to produce the desired phase lead or lag relationship and/or duty cycle relationship among the multiple frequencies provided by the RF bias power supply 122 and the RF power supply 128. The controller 140 generally includes a Central Processing Unit (CPU) 142, a memory 144, and a support circuit 146. The CPU 142 may be any form of a general-purpose computer processor that can be used in an industrial setting. The support circuit 146 is conventionally coupled to the CPU 142 and may comprise a cache, clock circuits, input/output subsystems, power supplies, and the like. Software routines, such as a method as described below may be stored in the memory 144 and, when executed by the CPU 142, transform the CPU 142 into a specific purpose computer (controller 140). The software routines may also be stored and/or executed by a second controller (not shown) that is located remotely from the process chamber 102.

The memory 144 is in the form of computer-readable storage media that contains instructions, when executed by the CPU 142, to facilitate the operation of the semiconductor processes and equipment. The instructions in the memory 144 are in the form of a program product such as a program that implements the method of the present principles. The program code may conform to any one of a number of different programming languages. In one example, the disclosure may be implemented as a program product stored on a computer-readable storage media for use with a computer system. The program(s) of the program product define functions of the aspects (including the methods described herein). Illustrative computer-readable storage media include, but are not limited to: non-writable storage media (e.g., read-only memory devices within a computer such as CD-ROM disks readable by a CD-ROM drive, flash memory, ROM chips, or any type of solid-state non-volatile semiconductor memory) on which information is permanently stored; and writable storage media (e.g., floppy disks within a diskette drive or hard-disk drive or any type of solid-state random access semiconductor memory) on which alterable information is stored. Such computer-readable storage media, when carrying computer-readable instructions that direct the functions of the methods described herein, are aspects of the present principles.

The conductance liner 110 is disposed in the process volume 112 about at least one of the substrate support assembly 104 and the upper electrode 106 to confine a plasma therein. In some embodiments, the conductance liner 110 is formed from a material such as polysilicon, silicon, silicon carbide, single crystal silicon, silicon carbide coated aluminum, polysilicon coated aluminum or the like, to advantageously reduce contamination on a substrate being processed. The conductance liner 110 may include an upper liner 160 and a lower liner 162. In some embodiments, the upper liner 160 rests on the lower liner 162. In some embodiments, the upper liner 160 and the lower liner 162 are integrally formed. In some embodiments, the lower liner 162 extends radially inward from the upper liner 160 so that the conductance liner 110 has a C-shaped profile. In some embodiments, an inner diameter of the upper liner 160 is greater than an inner diameter of the lower liner 162. The lower liner 162 includes a plurality of radial slots arranged around the lower liner 162 to provide a flow path to the vacuum pump 136.

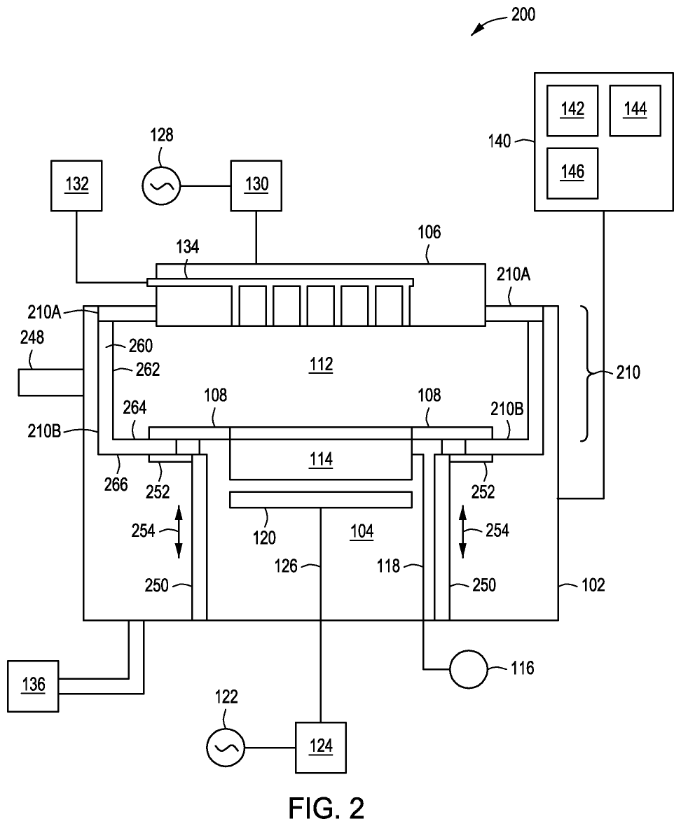

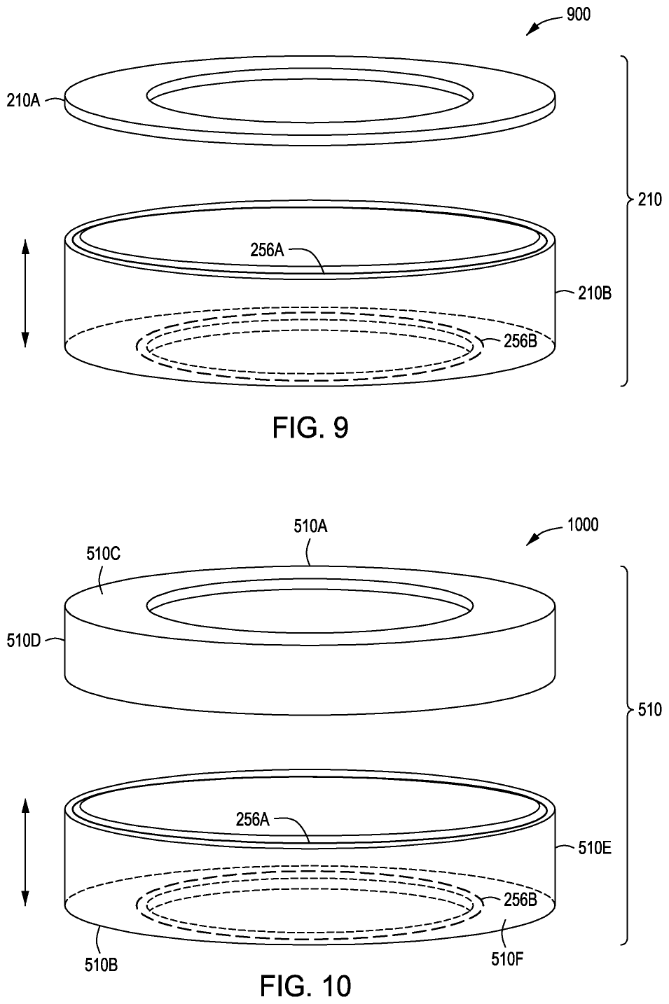

In the example of FIG. 1, a substrate transfer slot 138 breaches the conductance liner 110, disrupting an inner surface 111 and conductivity of the conductance liner, causing deposition uniformity issues. In the cross-sectional view 200 of FIG. 2, the breach has been removed and the conductance liner 110 of FIG. 1 has been replaced with a movable conductance liner 210 having a fixed portion 210A and a movable portion 210B. In some embodiments, the fixed portion 210A and the movable portion 210B, when in contact with each other, form a C-shaped profile. A substrate transfer slot 248 has been relocated to an outer wall 103 of the process chamber 102 and no longer breaches the movable conductance liner 210. In some embodiments, the fixed portion 210A of the movable conductance liner 210 is an annular shaped flat ring (see view 900 of FIG. 9, 210A) that surrounds the upper electrode 106. In some embodiments, the movable portion 210B of the movable conductance liner 210 is annular with an L-shaped profile (see FIG. 4, 410B and view 900 of FIG. 9, 210B) that surrounds the substrate support assembly 104. The movable portion 210B makes electrical contact with the fixed portion 210A at an upper end 260 of a vertical portion 262 of the movable portion 210B. The movable portion 210B makes electrical contact with the edge ring 109 on an upper surface 264 of a horizontal portion 266 of the movable portion 210B. The movable portion 210B is attached to an actuator 252 that is driven by a lift assembly 250. At least a portion of the movable conductance liner 210 may be formed from a material such as single crystal silicon, polysilicon, silicon carbide, a combination of silicon and silicon carbide, silicon carbide coated aluminum, polysilicon coated aluminum, or the like. The lift assembly 250 and actuator 252 provide vertical movement 254 to the movable portion 210B. The lift assembly 250 may be operated by a motor or by a pneumatically driven piston assembly (not shown). In some embodiments, more than one actuator 252 and lift assembly 250 may be used to provide vertical motion to the movable portion 210B. The lift assembly 250 may be incorporated into the substrate support assembly 104 and/or maybe incorporated independent of the substrate support assembly 104. In some embodiments, the actuator 252 may provide electrical isolation between the movable portion 210B and the substrate support assembly 104.

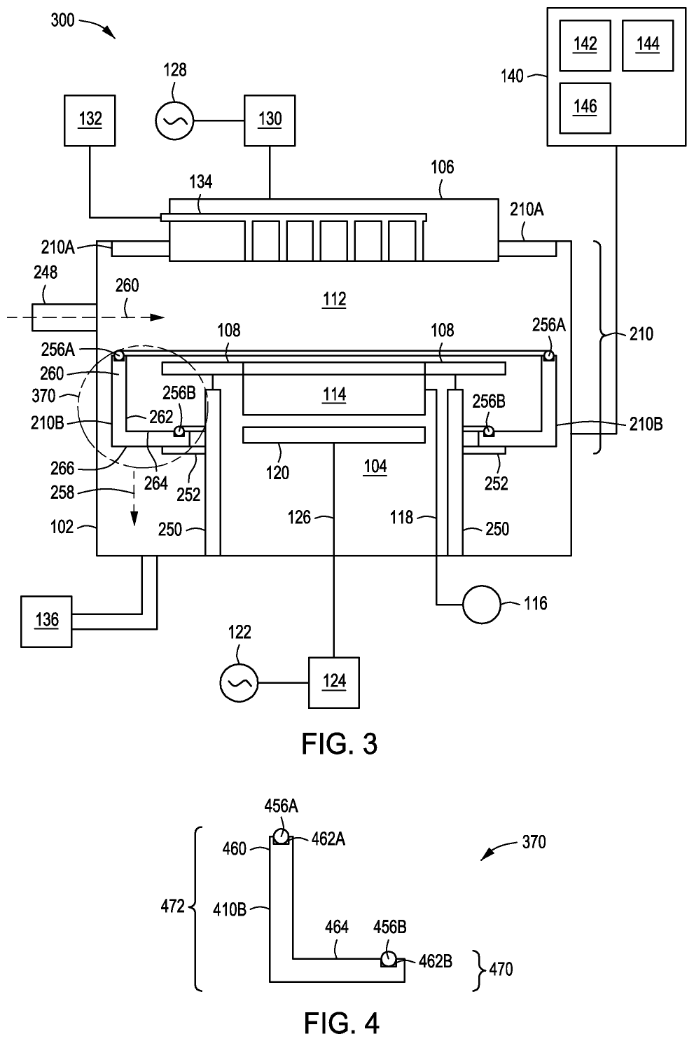

FIG. 3 is a cross-sectional view 300 of the process chamber 102 with the movable conductance liner 210 in a lowered position 258. In some embodiments, the movable portion 210B of the movable conductance liner 210 may have one or more RF gaskets 256A, 256B to improve electrical contact with the fixed portion 210A and/or the edge ring 108. The RF gaskets 256A, 256B may be o-rings made from a stainless-steel material which is compressible to form a tight electrical contact around the entire perimeters of the movable portion 210B. When the movable portion 210B is in the lowered position 258, the substrate transfer slot is available to allow a substrate to be placed into 260 the process chamber 102. After placement of the substrate on the substrate support assembly 104, the lift assembly 250 and actuator 252 move the movable portion 210B upward until the RF gaskets 256A, 256B compress against the fixed portion 210A and the edge ring 108. The controller 140 may control the process and/or receive feedback to know when the movable portion 210B has been lowered and/or when the movable portion 210B is in the up position. FIG. 4 depicts a cross-sectional view 370 of a movable portion 4106 in accordance with some embodiments. The movable portion 410B has a first recess 462A in an upper end 460 of a vertical portion 472 for a first RF gasket 456A and a second recess 462B in an upper surface 464 of a horizontal portion 470 for a second RF gasket 4566.

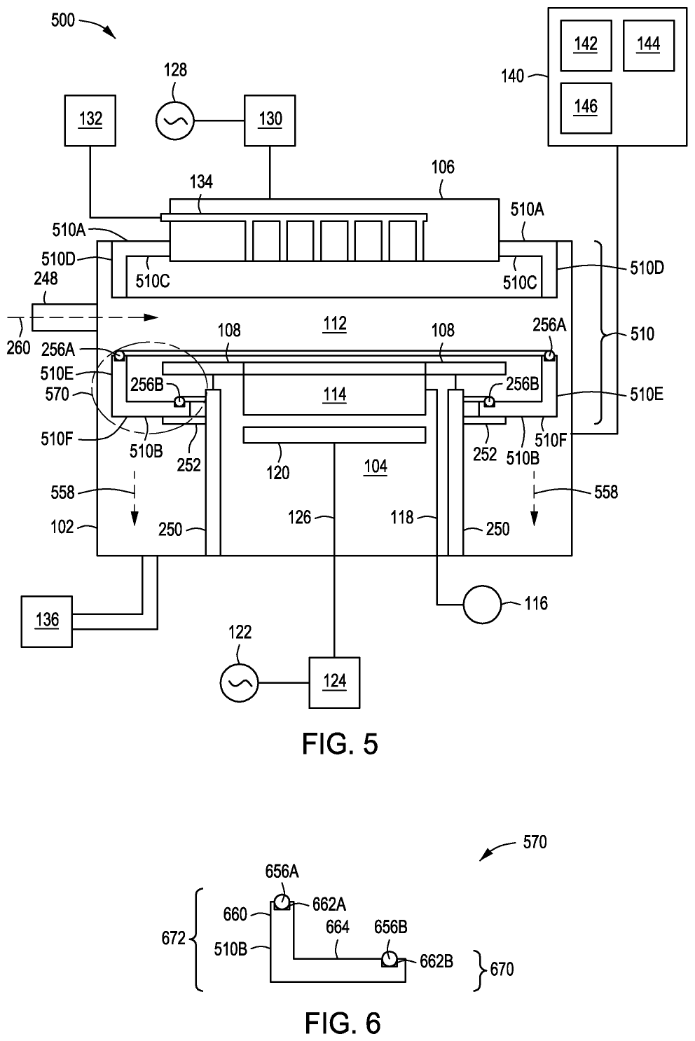

FIG. 5 depicts a cross-sectional view 500 of the process chamber 102 with a movable conductance liner 510 with a split vertical sidewall in accordance with some embodiments. A fixed portion 510A of the movable conductance liner 510 has a first horizontal portion 510C at a top of the process chamber 102 and a first vertical portion 510D, creating an L-shaped profile (see view 1000 of FIG. 10, 510C, 510D). The movable portion 5106 has a second horizontal portion 510F and a second vertical portion 510E, creating an L-shaped profile (see FIG. 10, 510E, 510F). In some embodiments, the fixed portion 510A and the movable portion 5106, when in contact, form a C-shaped profile. The first vertical portion 510D of the fixed portion 510A and the second vertical portion 510E may or may not have the same height. When the movable portion 5106 is in the lowered position 558, a substrate may be placed or removed from the substrate support assembly 104. At least a portion of the movable conductance liner 510 may be formed from a material such as single crystal silicon, polysilicon, silicon carbide, a combination of silicon and silicon carbide, silicon carbide coated aluminum, polysilicon coated aluminum, or the like. FIG. 6 depicts a cross-sectional view 570 of the movable portion 5106 in accordance with some embodiments. The movable portion 5106 has a first recess 662A in an upper end 660 of a vertical portion 672 for a first RF gasket 656A and a second recess 662B in an upper surface 664 of a horizontal portion 670 for a second RF gasket 656B.

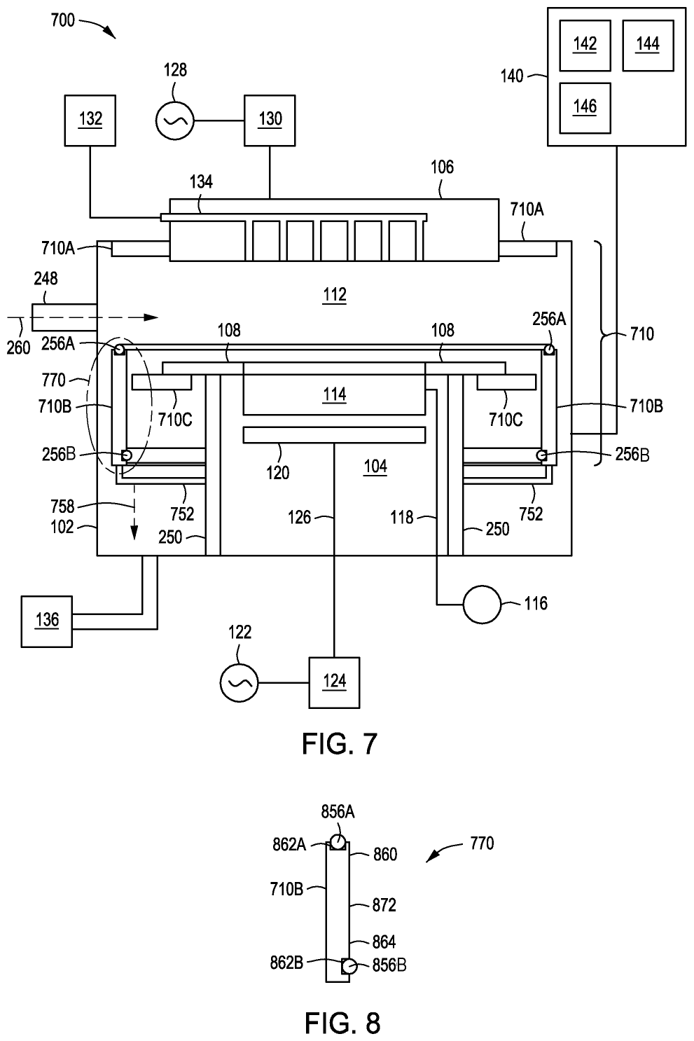

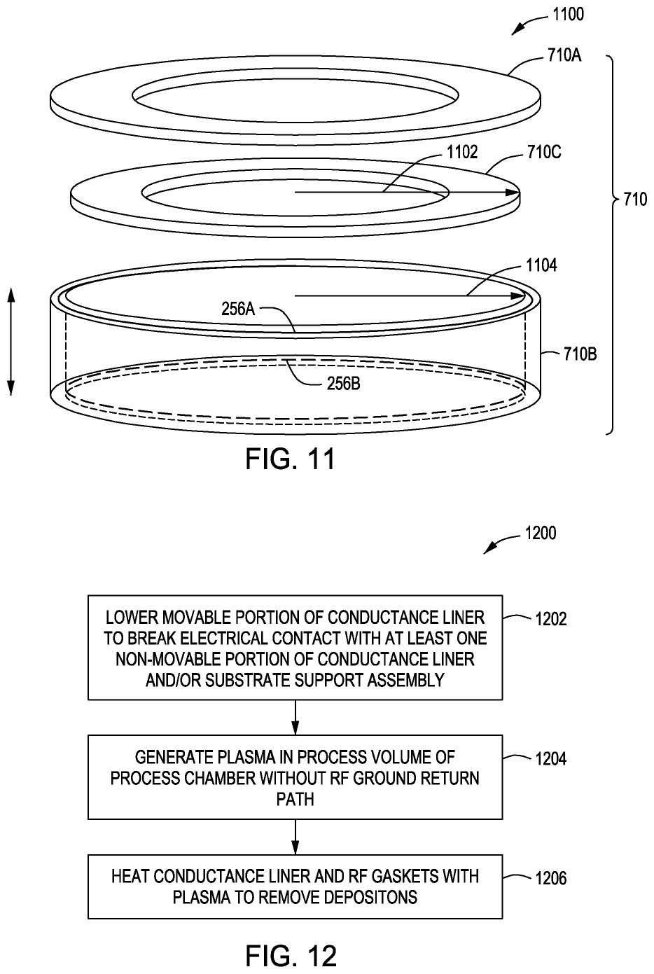

FIG. 7 depicts a cross-sectional view 700 of the process chamber 102 with a movable conductance liner 710 with a movable portion 710B in accordance with some embodiments. In some embodiments, the movable conductance liner 710 has more than one fixed portion, namely a first fixed portion 710A and a second fixed portion 710C (see FIG. 11, 710A, 710C). An actuator 752 from the lift assembly 250 is attached to the movable portion 710B. When the movable portion 710B is in the lowered position 758, a substrate may be placed or remove from the substrate support assembly 104. At least a portion of the movable conductance liner 710 may be formed from a material such as single crystal silicon, polysilicon, silicon carbide, a combination of silicon and silicon carbide, silicon carbide coated aluminum, or the like. As shown in a view 1100 in FIG. 11, an inner diameter 1104 of the movable portion 7106 is greater than an outer diameter 1102 of the second fixed portion 710C. The difference in diameters allows the movable portion 710B to move past the second fixed portion 710C untouched, making contact with the second RF gasket 256B when in a raised position. FIG. 8 depicts a cross-sectional view 770 of the movable portion 710B in accordance with some embodiments. The movable portion 710B has a first recess 862A in an upper end 860 of a vertical portion 872 for a first RF gasket 856A and a second recess 862B in a sidewall 864 of the vertical portion 872 for a second RF gasket 856B.

The apparatus described above may also be utilized during cleaning of a process chamber. FIG. 12 is a method 1200 of cleaning a process chamber with a conductance liner in accordance with some embodiments. An additional benefit of having a movable conductance liner is that the movable conductance liner can be moved to break the RF ground return path. At least a portion of the movable conductance liner may be formed from a material such as single crystal silicon, polysilicon, silicon carbide, a combination of silicon and silicon carbide, silicon carbide coated aluminum, polysilicon coated aluminum, or the like. In block 1202, a movable portion of a conductance liner is lowered to break the electrical contact with at least one non-movable portion of the conductance liner and/or a substrate support assembly. In block 1204, plasma is generated in a process volume of the process chamber without an RF ground return path. In block 1206, the conductance liner is heated with the plasma to remove depositions. In some embodiments with RF gaskets, the RF gaskets are cleaned along with the conductance liner during the cleaning process. The cleaning process facilitates in extending the life of the parts and also in maintaining deposition uniformities.

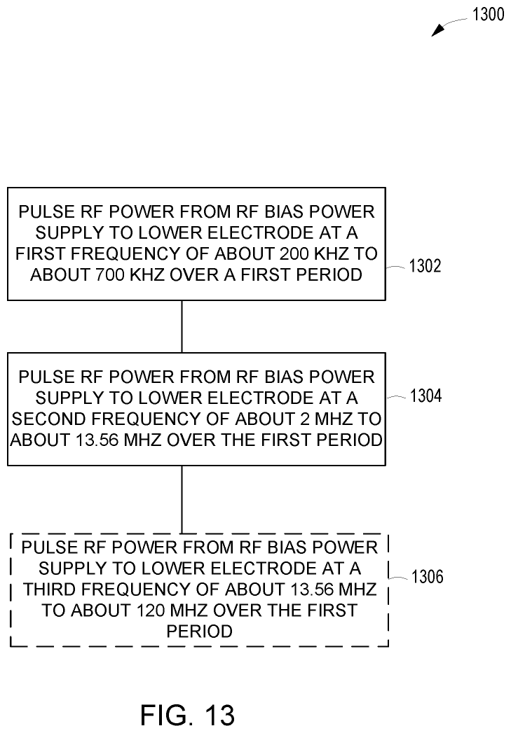

The apparatus described above may be utilized, for example, during an etching process. FIG. 13 is a method 1300 of processing a substrate in an etch process chamber (e.g., process chamber 102) in accordance with some embodiments. At 1302, the method 1300 includes pulsing RF power from the RF bias power supply to the lower electrode over a first period at a first frequency of about 200 kHz to about 700 kHz. A conductance liner (e.g., conductance liner 110) surrounds the process volume to provide a ground path for the RF power source. A substrate support (e.g., substrate support assembly 104) is disposed in the etch process chamber and includes an electrostatic chuck assembly (e.g., ESC assembly 114) coupled to a power supply (e.g., power supply 116) and a lower electrode (e.g., lower electrode 120) embedded therein and coupled to an RF bias power supply (e.g., RF bias power supply 122).

At 1304, the method includes pulsing RF power from the RF bias power supply to the lower electrode over the first period at a second frequency of about 2 MHz to about 13.56 MHz. Optionally, at 1306, the method includes pulsing RF power from the RF bias power supply to the lower electrode over the first period at a third frequency of about 13.56 MHz to about 120 MHz. In some embodiments, the first frequency is about 300 kHz to about 500 kHz. In some embodiments, the first frequency is about 400 kHz. In some embodiments, the second frequency is about 1 MHz to about 3 MHz. In some embodiments, the second frequency is about 2 MHz. In some embodiments, the third frequency is about 30 MHz to about 60 MHz. In some embodiments, the third frequency is about 40 MHz. When the RF bias power supply provides dual frequencies, the first frequency and the second frequency may be independently pulsed, phased, and/or duty cycle controlled over the first period. When the RF bias power supply provides triple frequencies, the first frequency, the second frequency, and the third frequency may be independently pulsed, phased, and/or duty cycle controlled over the first period

In some embodiments, the first frequency, the second frequency, and the third frequency are pulsed synchronously. In some embodiments, only two of the first frequency, the second frequency, and the third frequency are pulsed synchronously. In some embodiments, the first frequency, the second frequency, and the third frequency are pulsed asynchronously. In some embodiments, a plasma is formed in the process volume using a RF power supply (e.g., RF power supply 128) coupled to an upper electrode (e.g., upper electrode 106) of the process chamber. In some embodiments, power from the RF power supply is pulsed. In some embodiments, a movable portion (e.g., movable portion 210B, 410B, 5106, 710B) of the conductance liner is moved in a vertical direction to seal the movable portion with a fixed portion (e.g., fixed portion 210A, 410A, 510A, 710A) of the conductance liner to confine plasma therein and to provide a ground path for the plasma prior to pulsing RF power from the RF bias power supply. In some embodiments, the movable portion of the conductance liner is moved in a vertical direction to separate the movable portion from the fixed portion to facilitate moving the substrate into or out of the process volume.

Embodiments in accordance with the present principles may be implemented in hardware, firmware, software, or any combination thereof. Embodiments may also be implemented as instructions stored using one or more computer readable media, which may be read and executed by one or more processors. A computer readable medium may include any mechanism for storing or transmitting information in a form readable by a machine (e.g., a computing platform or a “virtual machine” running on one or more computing platforms). For example, a computer readable medium may include any suitable form of volatile or non-volatile memory. In some embodiments, the computer readable media may include a non-transitory computer readable medium.

While the foregoing is directed to embodiments of the present principles, other and further embodiments of the principles may be devised without departing from the basic scope thereof.

1. A method of processing a substrate in an etch process chamber, comprising:
pulsing RF power from an RF bias power supply to a lower electrode disposed in a substrate support of the etch process chamber at a first frequency of about 200 kHz to about 700 kHz over a first period to create a plasma in a process volume of the etch process chamber, wherein a conductance liner surrounds the process volume to provide a ground path for an upper electrode of the etch process chamber; and
pulsing RF power from the RF bias power supply to the lower electrode at a second frequency of about 2 MHz to about 13.56 MHz over the first period.

2. The method of claim 1, further comprising pulsing RF power from the RF bias power supply to the lower electrode at a third frequency of about 13.56 MHz to about 120 MHz over the first period.

3. The method of claim 2, wherein at least two of the first frequency, the second frequency, and the third frequency are pulsed synchronously.

4. The method of claim 2, wherein the third frequency is about 40 MHz.

5. The method of claim 1, wherein the first frequency is about 400 kHz.

6. The method of claim 1, wherein the second frequency is about 2 MHz.

7. The method of claim 1, wherein the first period coincides with a pulse duration of at least one of the first frequency and the second frequency.

8. The method of claim 1, further comprising moving a movable portion of the conductance liner in a vertical direction to seal the movable portion with a fixed portion of the conductance liner to confine plasma therein prior to pulsing RF power from the RF bias power supply.

9. The method of claim 8, further comprising moving the movable portion of the conductance liner in a vertical direction to separate the movable portion from the fixed portion to facilitate moving a substrate into or out of the process volume.

10. An etch process chamber, comprising:
a process chamber having a process volume therein;
a conductance liner surrounding the process volume, the conductance liner having a C-shaped profile; and
a substrate support assembly disposed in the processing volume, wherein the substrate support assembly includes an electrostatic chuck assembly coupled to a power supply and a lower electrode coupled to an RF bias power supply to provide RF power to the substrate support assembly.

11. The etch process chamber of claim 10, wherein the conductance liner comprises:
at least one fixed portion;
a movable portion, the movable portion configured to expose a substrate transfer slot in a wall of the process chamber; and
a lift assembly with an actuator attached to the movable portion of the conductance liner to move the movable portion of the conductance liner in a vertical direction.

12. The etch process chamber of claim 11, wherein the actuator provides electrical isolation between the movable portion and the substrate support assembly.

13. The etch process chamber of claim 11, wherein the at least one fixed portion of the conductance liner has a first horizontal portion at a top of the process chamber and the movable portion of the conductance liner has a vertical portion and a second horizontal portion, the vertical portion configured to interact with the fixed portion when the movable portion is raised and the second horizontal portion configured to interact with an edge ring when the movable portion is raised to complete an RF ground return path within the process chamber.

14. The etch process chamber of claim 11, further comprising an edge ring that interfaces with the conductance liner and the substrate support assembly.

15. The etch process chamber of claim 14, wherein the at least one fixed portion of the conductance liner has a first horizontal portion and a first vertical portion and the movable portion of the conductance liner has a second vertical portion and a second horizontal portion, the second vertical portion configured to interact with the first vertical portion when the movable portion is raised and the second horizontal portion configured to interact with the edge ring when the movable portion is raised to complete an RF ground return path within the process chamber.

16. The etch process chamber of claim 10, wherein the conductance liner is made of polysilicon, silicon, silicon carbide, single crystal silicon, silicon carbide coated aluminum, or polysilicon coated aluminum.

17. An etch process chamber, comprising:
a process chamber defining a process volume therein;
a conductance liner surrounding the process volume;
a substrate support disposed in the processing volume, wherein the substrate support includes a puck having a first electrode embedded therein and coupled to a chucking power supply and a second electrode embedded therein and coupled to a second RF power supply; and
an upper electrode having gas passages coupled to the process volume, wherein the conductance liner is disposed about the upper electrode.

18. The etch process chamber of claim 17, wherein the second RF power supply provides RF power at one or more frequencies to the substrate support.

19. The etch process chamber of claim 17, wherein the conductance liner is made of polysilicon, silicon, silicon carbide, single crystal silicon, silicon carbide coated aluminum, or polysilicon coated aluminum.

20. The etch process chamber of claim 17, wherein the conductance liner includes at least one first portion configured to be fixed in the process chamber; and a second portion configured to be movable within the process chamber in a vertical direction to expose a substrate transfer slot in a wall of the process chamber, the second portion configured to provide a portion of a RF ground return path when in a raised position and electrically interacting with the at least one first portion.
